(19) United States
(12) Patent Application Publication
(10) Pub. No.: US 2022/0361348 A1
(43) Pub. Date: Nov. 10, 2022

(54) FAST ASSEMBLY DISPLAY SCREEN

(71) Applicant: EBN Technology Corp., New Taipei City (TW)

(72) Inventors: CHIEN-LONG LIN, New Taipei City (TW); MING-JEN KUO, New Taipei City (TW)

(21) Appl. No.: 17/316,180

(22) Filed: May 10, 2021

(51) Int. Cl. H05K 5/02; H05K 5/00

(52) U.S. Cl. CPC H05K 5/0217; H05K 5/0017

(57) ABSTRACT

A fast assembly display screen, comprising: a panel, a front frame, and a plurality of thumb screws. The panel is provided with two opposite side edges, on a front end and rear end of each side edge are disposed a connection base respectively, and each connection base is provided with a female screw thread. The front frame is provided with a hollow area, for the panel to be pressed vertically downward to fasten and fix the front frame into the hollow area, to realize assembly of the panel and the front frame. A plurality of support slots are disposed on two opposite frame edges of the front frame, each of the support slots is aligned to the female screw thread of the corresponding connection base, so that in assembling the panel and the front frame, each support slot surrounds the female screw thread of the corresponding connection base. Each of the plurality of thumb screws can be screwed in through the support slot, to be locked onto the female screw thread of the corresponding connection base by a user's hand.

### BACKGROUND OF THE INVENTION

### Field of the Invention

The preferred embodiment of the present invention relates to a display screen, and in particular to a fast assembly display screen.

### The Prior Arts

In recent years, the electronic and information industries are developing rapidly, and the computer has become a necessity of our daily life. Also, the network communication technology is progressing by leaps and bounds. As such, our living, learning, work and entertainment have entered into a new frontier. Along with the advance of computer/information technology, the communication between people can be realized through network communication, such that information, advertisements, and e-mails can be exchanged via network real-time. In addition, online data search, online chat and online game can be achieved through getting on-line the Internet, to provide high speed and convenience to the user in living, learning, work and entertainment. Therefore, the connection between people and computer is essential and indispensable.

In general, data stored in a computer can be shown to the user by making use of a display, the display is used as an interface between user and computer. For the development of a Display from the Cathode Ray Tube (CRT) in early days to the Liquid Crystal Display (LCD) recently, the tendency of design is always aimed at light-weight, compact-structure, and thin-profile, to save the space occupied. Presently, an advanced Touch Control Display is introduced, and its main feature is that, a touch control panel is placed in the Display, to replace the conventional keyboard and mouse. In this way, in inputting data and/or instructions to the computer, all you have to do is to touch your finger or pen on the screen, without the need of complicated procedures. The touch control display is used mainly in the Industries and various information system inquires, to make the computer more user-friendly.

Usually, tablet computer and notebook computer are equipped with display screen, to give the user convenience and good hand feel in operation. The conventional display screen is equipped with a backplane, a panel, and a front frame. The front frame is of a hollow structure corresponding to the rectangular frame of the backplane. In assembling a display screen, the panel is pressed vertically downward, to be fastened and fitted onto the front frame. Subsequently, a tool is used to drive the screws to fix and lock the panel into the front frame. Then, the screws are used to fix and lock the front frame onto the backplane, to complete the assembly of the display screen.

As such, in the conventional way of assembly, firstly, panel is pressed vertically downward, to be fastened and fitted onto the front frame; then tool (screw driver) is used to fix and lock the panel onto the front frame. However, in this process, a tool such as a screw driver must be utilized, to cause additional material cost and inconvenience in assembly.

Therefore, presently, the design of the Touch Control Display is not quite satisfactory, and it leaves much room for improvements.

### SUMMARY OF THE INVENTION

In view of the problems and drawbacks of the prior art, the preferred embodiment of the present invention provides a fast assembly display screen, to solve the shortcomings of the prior art.

The preferred embodiment of the present invention provides a fast assembly display screen, and it includes: a panel, a front frame, and a plurality of thumb screws. Wherein, the panel is provided with two opposite side edges, on each of the front end and the rear end of each side edge, a connection base is disposed, and each connection base is provided with a female screw thread.

The front frame is provided with a hollow area, for the panel to be pressed vertically downward to fasten and fix the front frame into the hollow area of the front frame, to realize assembly of the panel and the front frame. A plurality of support slots are disposed on two opposite frame edges of the front frame, each of the support slots is aligned to the female screw thread of the corresponding connection base, so that in assembling the panel and the front frame, each support slot is adapted to surround the female screw thread of the corresponding connection base.

The plurality of thumb screws can each be screwed in through the support slot by a user's hand, to be locked onto the female screw thread of the corresponding connection base.

According to a preferred embodiment of the present invention, the front frame is of a rectangular shape, and the connection bases are disposed on two shorter side edges of the panel.

Further scope of the applicability of the present invention and given embodiments thereof will become apparent from the detailed descriptions hereinafter. However, it should be understood that the detailed descriptions and specific examples, while indicating preferred embodiments of the present invention, are given by way of illustration only, since various changes and modifications within the spirit and scope of the present invention will become apparent to those skilled in the art from these detailed descriptions.

### BRIEF DESCRIPTION OF THE DRAWINGS

Embodiments of the present invention are described below, by way of example only, with reference to the accompanying drawings in which:

FIG. 1 is an exploded view of a fast assembly display screen according to the present invention; and

FIG. 2 is an assembled view of a fast assembly display screen according to the present invention.

### DETAILED DESCRIPTION OF THE PREFERRED EMBODIMENT

The purpose, construction, features, functions and advantages of the present invention and its embodiments can be appreciated and understood more thoroughly through the following detailed descriptions with reference to the attached drawings.

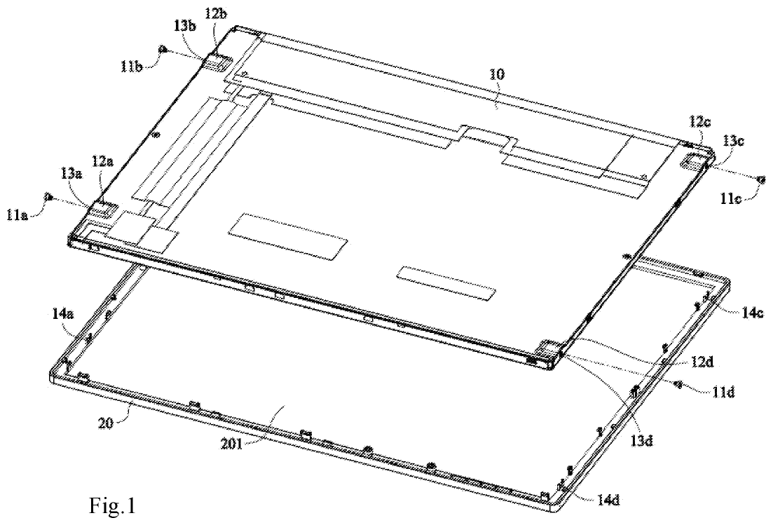

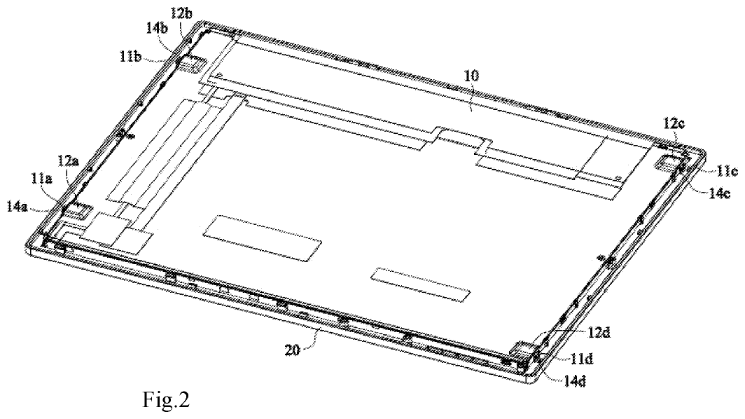

Refer to FIGS. 1 and 2 for an exploded view of a fast assembly display screen according to the present invention, and an assembled view of a fast assembly display screen according to the present invention respectively. As shown in FIGS. 1 and 2, the present invention includes: a panel 10, a front frame 20, and a plurality of thumb screws 11a, 11b,11c,11d. Wherein, the panel 10 is provided with two opposite side edges, on a front end and rear end of each side edge is disposed a connection base 12a, 12b,12c,12d respectively, and each connection base 12a, 12b,12c,12d is provided with a female screw thread 13a, 13b,13c,13d.

The front frame 20 is provided with a hollow area 201, for the panel 10 to be pressed vertically downward to fasten and fix the panel 10 into the hollow area 201 of the front frame 20, to realize assembly of the panel 10 and the front frame 20. A plurality of support slots 14a, 14b,14c,14d (since in FIG. 1, a part of front frame 20 is covered by the panel 10, so support slot 14b is not shown in the drawing) are disposed on two opposite frame edges of the front frame 20. Each of the support slots 14a, 14b,14c,14d is aligned to the female screw thread 13a, 13b, 13c,13d of the corresponding connection base 12a, 12b,12c,12d, so that in assembling the panel 10 and the front frame 20, each support slot 14a,14b,14c,14d is adapted to surround the female screw threads 13a, 13b, 13c, 13d of the corresponding connection base 12a, 12b,12c,12d.

The plurality of thumb screws 11a, 11b,11c, 11d are screwed in through the support slots 14a,14b,14c,14d respectively, and locked onto the female screw threads 13a,13b,13c,13d of the corresponding connection bases 12a, 12b,12c,12d respectively by a user's hand. Preferably, the front frame 20 is of a rectangular shape, and the connection bases 12a, 12b,12c,12d are disposed on two shorter side edges of the panel 10 respectively.

Summing up the above, the preferred embodiment of the present invention provides a fast assembly display screen, and it is characterized in that: on a front end and rear end of each of two opposite side edges of the panel, a connection base is disposed respectively. Each connection base is provided with a female screw thread. and a plurality of support slots are disposed on two opposite frame edges of the front frame. Each of the support slots is aligned to the female screw thread of the corresponding connection base, so that in assembling the panel and the front frame, all it has to do is to press the panel vertically downward to fasten and fit into the hollow area in the front frame. A plurality of thumb screws are provided, each of the plurality of thumb screws can be screwed in through the support slot, to be locked into the female screw thread of the corresponding connection base. As such, through using the fast assembly display screen of the present invention, the user is allowed to assemble or detach a display screen swiftly, in achieving convenience for assembly of the display screen.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A fast assembly display screen, comprising:
a panel, provided with two opposite side edges, on a front end and rear end of each side edge is disposed a connection base respectively, and each connection base is provided with a female screw thread;
a front frame, provided with a hollow area, for the panel to be pressed vertically downward to fasten and fix the front frame into the hollow area of the front frame, to realize assembly of the panel and the front frame, a plurality of support slots are disposed on two opposite frame edges of the front frame, each of the support slots is aligned to the female screw thread of the corresponding connection base, so that in assembling the panel and the front frame, each support slot is adapted to surround the female screw thread of the corresponding connection base; and
a plurality of thumb screws, each of the plurality of thumb screws is screwed in through the support slot, to be locked onto the female screw thread of the corresponding connection base by a user's hand.

2. The fast assembly display screen as claimed in claim 1, wherein the front frame is of a rectangular shape, and the connection bases are disposed on two opposite short side edges of the panel respectively.
